(19) United States
(12) Patent Application Publication
(10) Pub. No.: US 2009/0233014 A1
(43) Pub. Date: Sep. 17, 2009

(54) Photoactive Film, Its Preparation And Use, And Preparation Of Surface Relief And Optically Anisotropic Structures By Irradiating Said Film

(76) Inventors: Joachim Stumpe, Nauen (DE); Leonid Goldenberg, Berlin (DE); Olga Kulikovska, Berlin (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(21) Appl. No.: 11/721,407

(22) PCT Filed: Dec. 8, 2005
(86) PCT No.: PCT/EP05/56612

§ 371 Date: Jun. 11, 2007

(30) Foreign Application Priority Data
Dec. 9, 2004 (EP) 04029263.3

(51) Int. Cl. G03F 7/00; B29C 41/00; G03F 7/004; H01G 9/022; B29C 39/00; B29C 35/00

(52) U.S. Cl. 428/29; 428/195.1; 428/156; 427/553; 264/227; 430/2; 430/270.1; 252/62.2; 264/299; 264/494; 430/286.1

(57) ABSTRACT

The present invention relates to a homogeneous, photoactive film consisting of or comprising a polyelectrolyte carrying residues which may undergo a photoreaction, the polyelectrolyte mainly comprising at least one structure according to any of formulae (I) to (IV), namely [Pol(R*—P—R′)]ₒ^{on+n/xA}^{x-} (I), n/xA^{x+}[Pol(R*—P—R′)]ₒ^{on-} (II), [Pol(R¹*-Q-R^{1′})]ₒ^{on+n/xΛ}^{x-} (III), n/xΛ^{x+}[Pol(R¹*-Q-R^{1′})]ₒ^{on-} (IV), wherein Pol means a repeating unit of a linear or branched polymer chain, o indicates the number of the repeating unit of the polymer chain, and (R*—P—R′) and (R¹*-Q-R^{1′}) are n-fold positively or negatively charged side chains of the repeating unit Pol, wherein P is a group which is capable of photo-induced E/Z isomerization, Q is a group capable of participating in a photocycloaddition, or capable of participating in a photoinduced rearrangement, or the so called Photo-Fries reaction, A is a cation or anion which is oppositely charged, n is preferably 1 or 2, x is 1 or 2, and o is at least 2, with the proviso that in one polyelectrolyte, groups [R—P—R′] and/or [R¹-Q-R^{1′}] all have the same sign. The invention is further directed to the preparation of the film, its use and a method for the preparation of a replica of a film of the invention having a surface relief structure.

The present invention relates generally to a new type of film forming material having unique photochemical properties. Non-scattering, optically clear films formed from the new materials can be easily prepared. They allow light-induced generation of optical anisotropy (photo-induced dichroism and birefringence) therein and of topological surface structures, e.g. such as surface relief gratings (SRG). The material comprises or consists of a charged polymer with photosensitive, side groups having the ability to undergo E/Z isomerisation or to participate in a light induced cycloaddition or in a photoinduced rearrangement reaction or another reaction capable of generating optical anisotropy in the material upon irradiation. The material readily forms films, preferably on solid substrates or between two such substrates from water/alcoholic or organic solvents.

It is known that amorphous and liquid crystalline polymers containing azobenzene or other photoactive moieties such as stilbenes, cinnamates, coumarins in side chains or main chains can be used for the induction of anisotropy by photoorientation (K. Ichimura, Chem. Rev. 2000, 100, 1847; A. Natansohn et al., Chem. Rev. 2002, 102, 4139; V. Shibaev et al., Prog. Polym. Sci. 28 (2003) 729-836; X. Jiang, et al., WO 98/36298). Azobenzene derivatives are also known for their ability to form SRG when being exposed to gradient light field (A. Natansohn et al., supra).

Different types of azobenzene containing materials were used for optical anisotropy and/or SRG generation. In one approach (“guest-host” systems), this was attained by mixing of photochromic azobenzene derivatives, e.g. 4-[4-N-n-hexyl-N-methylamino-phenylazo]-benzoic acid or modified Direct Red 1 azodye with readily available polymer PMMA as a matrix (J. Si et al., APPL. PHYS. LETT. 80, 2000, 359; C. Fiorini et al., Synthetic Metals 115 (2000), 121-125). However, the effects to be observed are rather weak, due to low dye loading caused by dye-polymer segregation. Relatively high loading of the photochromic material in the polymer matrix could be observed with specially synthesized dyes, which allow avoiding a dye-polymer segregation (C. Fiorini et al., see above). But in such systems the photo-induced dichroism was not stable, and the SRG formation was not effective (up to 50 nm deep). Relatively stable birefringence has been induced only when commercially available Direct Red 1 was introduced into very high-T_{g} poly(ether ketone). It is unknown whether SRGs can be generated in the latter system. Such materials were used for the recording of orientational holograms.

Better results have been obtained by chemically binding azodye compounds to a polymeric material. The material is characterized by covalent bonds between the photoactive units and the polymeric backbone. In addition to the fact that the results observed are much better than in the “guest-host” approach, such polymer materials normally have good film forming properties. However, environmentally non-friendly organic solvents have to be used. Often the solubility of the polymers is a problem which is hardly to overcome. Special synthesis is required to manufacture such functional polymers from commercially available chemicals, and consequently, they are expensive. Moreover, the purification of the polymers is a difficult problem as well.

Recently, a specially synthesized monomeric azobenzene derivative has been found which is able to form glassy films (V. Chigrinov et al., 1106 • SID 02 DIGEST; V. A. Konovalov, et al., EURODISPLAY 2002, 529; W. C. Yip et al., Displays, 22, 2001, 27). In films of these low molecular weight glass forming compounds optical anisotropy was induced by irradiation with linearly polarised light.

Moreover, a layer-by-layer (LBL) dipping procedure has been employed to obtain films for photo-induced orientation and SRG formation (see e.g. A. M.-K. Park et al, Langmuir 2002, 18, 4532; Ziegler et al., Colloids and Surfaces, A 198-200 (2002), 777-784; V. Zucolotto et al., Polymer 44 (2003), 6129-6133). In such systems, readily available polyelectrolytes and low molecular weight azodyes possessing at least two ionic groups, azobenzene containing bolaamphiphiles, ionenes or polyelectrolytes covalently substituted with azobenzene moieties are used. In the typical procedure, a substrate is alternately immersed for about 10-20 min in an aqueous solution of a cationic polyelectrolyte, such as poly-DADMAC, and an anionic azobenzene containing compound, respectively. Each immersion results in the formation of a monolayer on the substrate surface with typical thickness of about 1 nm. Numerous repetition of this procedure results in a multilayer film. About 150 layers are required to obtain a reasonable thickness of the resulting layer. Films up to 700 layers can be produced. SRGs with an amplitude of up to 120-140 nm can be generated, wherein a photoinduced orientation of the azobenzene moieties can be observed. The procedure is tedious and time consuming. Moreover, rather thick films are necessary for the inscription of deep SRG, and such films are difficult to obtain.

Another approach using H-bonds between the polymeric backbone and the photochromic compounds has been employed (E. B. Barmatov et al., Polymer Science, Ser. A, Vol 43 (3), 2001, 285). In this way, films with the ability for photoorientation were obtained.

In these concepts, the components are bound to each other by Coulomb attraction or H-bonds. Similar attraction is possible between oppositely charged ionic moieties in solution. The interaction of polyelectrolytes with dyes in dilute solutions has been studied (W. Dawydoff et al., Acta Polym. 1991, 42, 592). Recently, complexes of polyelectrolytes with another, oppositely charged polyelectrolyte containing a diazosulfonato moiety in the side chain were fabricated as a solid material (A. F. Thunemann et al., Macromolecules 1999, 32, 7414; 2000, 33, 5665). The molecular photochemistry and light-induced subsequent physical processes of these materials such as photoorientation and photo-induced diffusion, were not investigated.

In summary, a multiplicity of chemical systems making use of the photochemical properties of photochromic azobenzene dyes has been developed during the past few years. Such compositions may form films, which allow introduction of optical anisotropy and/or the generation of surface relief structures therein. However, despite the intense search for effective and readily available compositions, they are all connected with certain disadvantages as outlined above.

The inventors found that a material having the below chemical properties can be used as the or part of the material for a photoactive film combining high efficiency of the induction of optical anisotropy as well as of surface relief structures with the simplicity of material preparation. The material consists of or comprises a polymer with photosensitive, charged side groups having the ability to undergo E/Z isomerisation or to participate in a light induced cycloaddition or in a photoinduced rearrangement reaction or the like. Further components such as plasticizers, conventional organic oligomers or polymers, other photosensitive compounds, dyes, or liquid crystalline compounds can be added to modify formulation properties, and the properties of the films (flexibility of the film, hydrophilic/hydrophobic properties and the like). The said materials readily form films on solid substrates from water/alcoholic or organic solvents. Optical anisotropy and/or surface relief structures can be induced in these films upon irradiation with light.

The photosensitive polymer suitable for the present invention is a polyelectrolyte the charged side chains of which are capable to undergo a photoreaction, mainly selected from photoisomerization, photocycloaddition reactions and photoinduced rearrangements. If they are capable to undergo a photoisomerization, the polymer substantially consists of or mainly comprises a structure according to formula I or II

[Pol(R*—P—R′)]ₒ^{on+}no/xA^{x-} (I),

or

no/xA^{x+}[Pol(R*—P—R′)]ₒ^{on-} (II),

wherein Pol means a repeating unit of a linear or branched polymer chain of the polyelectrolyte, o indicates the number of the repeating unit in the polyelectrolyte and (R*—P—R′) and (R¹*-Q-R^{1′}) are n-fold positively or negatively charged side chains of the repeating unit Pol, whereby
P is a group which is capable to undergo photo-induced E/Z isomerization,
R* is selected from optionally substituted and/or functionalized aryl-containing groups bound to the repeating unit Pol and to group P,
R′ is selected from optionally substituted and/or functionalized aryl-containing groups,
wherein at least one of R* and R′ is positively or negatively charged,
A is a cation or anion which is oppositely charged,
n is preferably 1 or 2, more preferably 1, but may in specific cases be higher (3 or 4),
x is 1 or 2, and
o is at least 2, preferably between 2 and 1000, but can be even higher.

Preferably, P is an azo group —N═N—, or comprises more than one such group. However, the invention is not restricted to compounds of formulae I or II containing one or more azo groups. For example, P may be —C═N— or, —C═C—. It is preferred in any of the mentioned cases that at least one, or preferred both of the aryl moieties are directly bound to the group P.

If the polyelectrolyte side chains are capable to undergo a photocycloaddition or photoinduced rearrangement, the polymer substantially consists of or mainly comprises a structure according to formula III or IV:

[Pol(R¹*-Q-R^{1′})]ₒ^{on+}no/xA^{x-} (III),

or

no/xA^{x+}[Pol(R¹*-Q-R^{1′})]ₒ^{on-} (IV)

wherein
Q is a group capable of participating in a photocycloaddition, preferably a (2+2) addition or a (4+4) addition, or capable of participating in a photoinduced rearrangement, preferably the rearrangement of spiropyranes to merocyanines, or the so called Photo-Fries reaction,
R¹* is selected from optionally substituted or functionalized groups which have electron-accepting properties and is bound to the repeating unit Pol and to group Q,
R^{1′} is selected from optionally substituted or functionalized groups which have electron-accepting properties or comprise at least one aryl moiety or such (a) group(s) which together with Q form an aryl ring or heteroaryl ring,
wherein at least one of R¹* and R^{1′} is positively or negatively charged, or wherein the ring structure comprising R^{1′} and Q and/or a substituent thereon will carry at least one positive or negative charge,
and A, n, and x are defined as for formulae (I) and (II) above.

In case the photocycloaddition is a (2+2) addition, Q will preferably contain a —C═C— or a —C═N— bond and will more preferably consist of the group —CR²═CR^{2′}— or —CR²═N—wherein R² and R^{2′} are independently selected under H or a C₁-C₄ group. Preferably, Q is part of a conjugated pπ-electron system. Examples for respective compounds are cinnamates, imines, stilbenes, chalcones, or p-phenylene diacrylic esters or amides, wherein at least one of R¹ and R^{1′} is an optionally substituted or functionalized phenyl or other aryl or heteroaryl ring and the other is also an optionally substituted or functionalized phenyl or other aryl or heteroaryl ring or a carboxylic ester or carbonamide group or a phenyl carbonyl residue. All the said groups or residues may be substituted or functionalized, and at least one of R¹ and R^{1′} must carry at least one positive or negative charge. Alternatively, Q may be a —C═C— group which is part of a carbocyclic or heterocyclic, preferably aromatic ring, e.g. in coumarins, in thymine or cytosine derivatives or in maleinic acid anhydride derivatives. According to the above definition, R¹ and R^{1′} are in such cases fused to form a ring structure, together with Q. One or more atoms of this ring structure or, alternatively, a substituent attached thereto may carry the respective at least one positive or negative charge. Again, such compounds, if carrying at least one positive or negative charge, will fall under the scope of the present invention.

In specific cases, when the photocycloaddition is not a (2+2) cycloaddition, Q may comprise more atoms in its backbone and may e.g. be an aromatic C₆ ring which can be fused within an aromatic system or may carry suitable residues at least one of which carries the respective charge(s). One example is an anthracene derivative. Anthracenes are known to undergo a (4+4) cycloaddition whereby carbon atoms 9 and 10 will form bridges to a neighbour atom, resulting in formation of a sandwich-like dimer structure.

Polymers having structures (I) to (IV) may carry more than one photosensitive group per side chain. For example, the side chains of said polymers may include bisazobenzene or trisazobenzene groups as well as diacrylic ester compounds, e.g. p-phenylene-diacrylic esters.

If R*, R′, R¹* and/or R^{1′} is an aryl or aryl containing group, it may be or may comprise a homocyclic or heterocyclic ring. Optionally, this ring may be fused to an aromatic system, e.g. a naphthalene or anthracene system. Further, the ring can be substituted or functionalized by one or more substituents.

In the definitions given above, the term “functionalized” shall mean substituted by a substituent which implies an additional functionality to the molecule, e.g. a substituent carrying a charge, like a SO₃H group, or a substituent which can provide the capability of polymerization or polyaddition, e.g. a S—H group, or a polymerizable —C═C-group. The term “substituted” shall mean any other substituent.

The compounds as defined above may be used in any kind of salts as available, e.g. ammonium or sodium salts, chlorides, sulfates and the like, or they may be acidic or basic compounds e.g. carboxylic acids, sulfonic acids, amines, or a hydroxy group carrying compounds, and the like, which are capable of reacting with an oppositely charged polyelectrolyte to yield a respective ionic complex. As outlined above, they can be positively or negatively charged, with one or more charges.

Pol can for example be an optionally substituted polyalkylenic unit, preferably a C₂-C₆ polyalkylene unit, for example an ethylenic unit —CH₂—CH₂—, wherein one of the carbon-bound hydrogen atoms is replaced by R* or R¹*. Instead, Pol may comprise or consist of an alkyleneoxide or alkylenamine, preferably a C₂-C₆ alkyleneoxide or alkyleneamine, e.g. —CH₂—CH₂—O—, or —CH₂—CH₂—NH—, wherein one of the hydrogen atoms bound to C or N is replaced by R* or R¹*. R* and R¹* can be bound to Pol either via carbon-carbon bonds, but also by way of an ether, ester, amine, amide, urea, guanidino, or sulfonamido or a comparable group. Attachment via a sulfonamido group is preferred; its orientation such that the amino group is bound to Pol is most preferred. In the above mentioned embodiments of Pol, it itself is not charged, which means that the charges are on the groups (R*—P—R′) or (R¹*-Q-R^{1′}), respectively. The structures can then be defined to be

[Pol(R*—P—R′ⁿ⁺)]ₒno/xA^{x-} (I′),

or

no/xA^{x+}[Pol(R*—P—R′ⁿ⁻)]ₒ (II′),

or

[Pol(R¹*-Q-R^{1′n+})]ₒno/xA^{x-} (III′),

or

no/xA^{x+}[Pol(R¹*-Q-R^{1′n-})]ₒ (IV′)

Alternatively, units Pol are charged themselves, e.g. may carry an alkylsulfonate group or alkylammonium group or the like, while the groups (R*—P—R′) and (R¹*-Q-R^{1′}), respectively, are also charged or are uncharged.

The expression “essentially consisting”, used in connection with the above structures (I) to (IV) shall mean that the said structures constitute the main body of the polyelectrolyte. Of course, a unit [Pol(R*—P—R′)ⁿ⁺] or any other of the above mentioned units (I) to (IV) cannot exist at the beginning and at the end of the polymer chain, and it is to be understood that the said units will carry an additional substituent, in most cases hydrogen, or eventually an alkyl group (e.g. C₁-C₄) bound to Pol. The polyelectrolyte of the present invention may be a homopolymer, i.e. comprising immediately subsequent units of Pol. Alternatively, it may consist of a copolymer (statistic or graft copolymer). In this connection, the expression “mainly comprising” shall mean that the chain of “Pol” units can be interrupted and/or that up to half the units (in terms of weight and/or of number) may be replaced by other 2-binding groups, e.g. Pol units which do not carry any of the above defined P or Y containing, photosensitive side chains, or other copolymerizing units, which carry no or other functional or non-functional groups, e.g. carbonic acid or ester groups, ethylenically unsaturated groups, or the like. In other cases, one or more unit [Pol(R*—P—R′)ⁿ⁺] or any other of the above mentioned units (Ia) to (IVa) may be replaced by a trivalent unit in order to obtain a branched second electrolyte.

In order to obtain the material of the present invention, the photosensitive polyelectrolyte as defined above is dissolved in a suitable solvent. Since the polyelectrolyte is ionic, it is usually soluble in protic and polar solvents, in most cases in water or a lower alcohol or a mixture of both. The solution is preferably considerably concentrated, often up to saturation. Additives may be incorporated at any stage prior to forming the films, as appropriate. They may either be added to the solution or may be added to the polyelectrolyte of the invention in any stage. Additives may be, for example, organic polymers, compounds having film forming abilities, plasticizers, liquid crystals and/or other, e.g. monomer, low molecular photosensitive compounds

The polyelectrolyte according to the present invention is rather stable, due to its ionic character. Specifically, it will be resistant against the influence of heat in a much larger extent than comparable materials which are not of ionic nature. Such materials will in general soften at lower temperatures.

In a specific embodiment of the invention, the materials of the present invention comprise the photosensitive polyelectrolyte, together with one or more additional components which may undergo or provide cross-linking of the film, preferably after structurization. Such components may be selected from additional organic monomers which are capable to bind to specific groups of the polyelectrolyte, forming bridges and/or an organic network. In one embodiment, this component is selected from monomeric photosensitive molecules which are capable to undergo photopolymerisation or photo-crosslinking. Preferably, the conditions of photopolymerisation or crosslinking should be such that a wavelength is used which is different from that used for “recording” (SRG formation) as mentioned above. In another embodiment, this component is susceptible to thermal curing or polymerizes/provides bridges or a cross-linking network upon thermal treatment.

Depending on the solvent, any of the conventional film forming techniques like spin-coating or casting, doctor's blading and the like can be used to prepare homogeneous films on a substrate in merely one step. In addition, ink-jet printing to produce patterned films, is also readily available using e.g. water/alcoholic media. After the film has been deposited on the substrate or the respective basic layer, it is allowed to dry, preferably at room temperature, for example in air.

The thickness of the films may vary in a broad range, depending on the desired application. For example, it may vary between 10 nm and 50 μm, typically between 200 nm and 5 μm. If desired, additional layers may be deposited, either between the substrate and the film of the inventive photosensitive material and/or as one or more covering layers on the upper surface of the film.

The photoactive material according to the invention is light-sensitive, due to the presence of groups in the polyelectrolyte which may either undergo light-induced E/Z isomerization and/or photocycloaddition reactions, or light induced rearrangement reactions. Under homogeneous irradiation with polarized actinic light, optical anisotropy is induced within films made from this material. The optical anisotropy may be stable, unstable or erasable in dependence on the material composition, treatment and irradiation conditions, as outlined below. Under inhomogeneous irradiation, both a modulation of optical anisotropy and a deformation of film surface may be achieved. Most surprisingly, the latter process is as effective or even more effective as reported for azobenzene containing functionalized polymers that have been known as the most effective for the surface relief gratings formation. In this regard the material of the present invention is a viable alternative to the covalently bonded polymer systems used until now.

As mentioned above, the properties of the proposed material may be optically modified in different ways. If irradiated homogeneously with polarized light, the film becomes anisotropic, that means, birefringence and/or dichroism are induced. This is due to a photoorientation process in the steady state of the photoisomerization in the material upon polarized irradiation. For example, if the material contains groups which undergo E/Z isomerization, light irradiation will result in an orientation of such groups. In case of photocycloadditions or other photoreactions, an angular-selective photo-decomposition or angular-selective formation of photoproducts will be observed.

The optical anisotropy induced in such a way may relax back, be erased thermally or by irradiation with light, or may be stable. For example since Z isomers relax back to the thermodynamic stable E isomers, the induced orientation based on the E/Z isomerization may be stable, may undergo relaxation, or may be erased thermally or photochemically. Thus, the optical anisotropy of azobenzene systems is only temporary induced (while surface relief gratings formed therewith are long-term stable, see below). However, optical anisotropy and surface gratings due to photocycloaddition will remain stable since the reaction is not reversible. Stability of optical anisotropy may also be achieved by using a material which allows further curing or crosslinking, e.g. by building up an organic network within the film. In such cases, light induced optical anisotropy may be “frozen” in the material when the material is cured after inducing said anisotropy.

The velocity of the induction and relaxation processes, if any, may be controlled through adjusting the temperature and/or the parameters of irradiating/erasing light. In this way a variety of thin film polarization elements like polarizer or retarder may be created that may be permanent or optically switchable. The light-induced change of birefringence or dichroism in this material may be also effectively used for optical data storage and, if reversible, for optical processing.

If a film is irradiated with an inhomogeneous light field, i.e. a light field wherein the intensity or/and polarization of irradiating light is spatially modulated, the induced anisotropy is correspondingly modulated through the film. One example of this is irradiation through a mask. In this way, pixel thin film polarization elements may be fabricated. Another example is irradiation with an interference pattern, i.e. holographic irradiation. In this way, a variety of holographic optical elements operating in transmission or reflection modes (like polarization beam splitter or polarization discriminator) may be realized.

Moreover, surface relief structures may be generated on the free surface of films made from the material of the present invention by inhomogeneous irradiation with polarized light (holographic, mask or near-field exposure). Surface relief structures may be a result of a photo-induced mass transport upon an E/Z photoisomerization reaction or upon photocycloaddition or photoinduced rearrangement reaction (e.g. caused by shrinkage due to ring formation).

If a film made of the material of the present invention is irradiated inhomogeneously, formation of surface relief structures (surface relief gratings, SRGs) can be observed along with the generation of inhomogeneous optical anisotropy. However, formation of SRGs can, if required or desired, be suppressed by irradiating a film between two substrates. In respect to reversibility and irreversibility of surface relief structures, the same applies as outlined above for the occurrence of optical anisotropy.

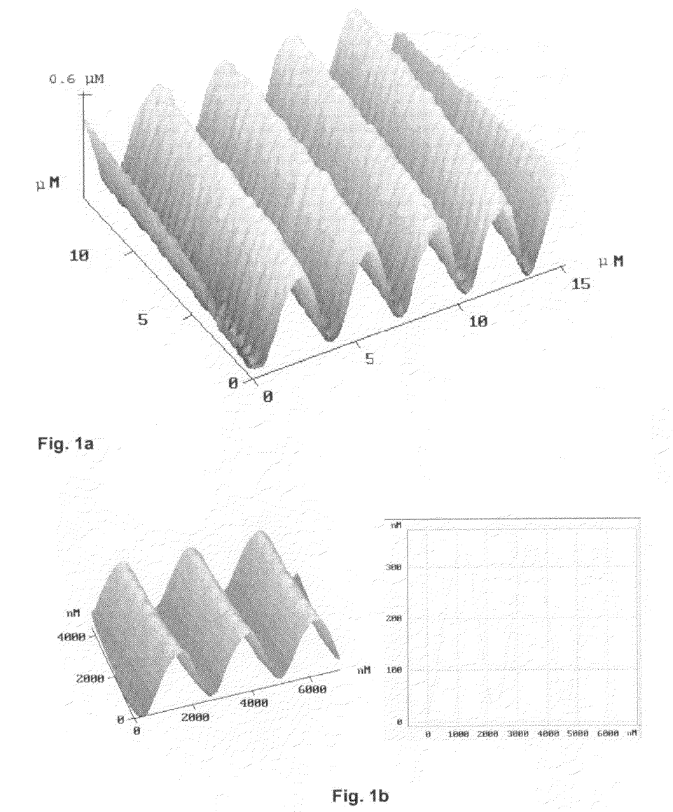

The lateral size of generated relief structures ranges from tens of nanometers (in the case of irradiation with near-field) up to the dimension of micrometers provided by holographic irradiation. It is being demonstrated here that the efficiency of the relief formation is comparable to the values reported for the azobenzene functionalized polymers (modulation depth of 0.6 μm was achieved in first, not yet optimized tests). Atomic force microscopy (AFM) images of SRG written in the materials of the present invention and, for comparison, in side chain azobenzene polymers of the prior art are shown in FIG. 1.

There are unique possibilities of the material application, due to the reversibility of the recording process, if a material is selected which allows reversible formation of surface relief structures. Once a relief structure has been recorded, it may be overwritten again. This allows the recording of complicated surface structures by superimposing their simple components. In this way, for example, multidimensional structures may be realized by successive recordings of simple one-dimensional structures; gratings with non-sinusoidal profile may be formed by successive recording of Fourier components or any recorded structure may be in a point way corrected. Another benefit of the reversibility of the process is the possibility of multiple use of the film. A high number of writing cycles without fatigue is possible. On the other hand, if generated in the material with additive as described above, the final relief structure may be “frozen” or fixed, for example, thermally or by flood exposure (exposure of the whole film) in order to obtain cross linking or the like and to avoid destruction of the resulting relief.

In this way a variety of relief holographic elements like diffraction grating, beam coupler, beam multiplexer, splitter or deflector, Fresnel lens and the like may be created. Applications of structured films (in particular gratings) are not restricted to optical elements only. One step all-optical structured surfaces may be used as templates for self-organisation of particles, as command surface for alignment of liquid crystals, as surface with modified wetting/dewetting properties or as antireflective layers.

If surface relief structures have been prepared according to the invention, such structures may be replicated using a wide variety of different materials. Replication may be performed once or manifold. A replica may again serve as template for replication. Materials which are useful for replication are known in the art. Examples are polysiloxanes, e.g. polydimethylsiloxane. Such materials may be prepared as resins having sufficiently low viscosity to fill the fine structures of the SRG and may be dried or cured after replication to yield a stable material. Other examples are polyacrylate resins, polyurethanes, ene-thiol compositions or a metal, e.g. via electrochemical deposition from a metal solution. The initial surface relief structure can be washed out from the replica, if desired, using an appropriate solvent.

The materials of the present invention have, inter alia, the following advantages: they can be manufactured from readily available non-expensive commercial materials, namely commercially available polyelectrolytes and photochromic derivatives with ionic groups. There is a great flexibility in their preparation, as well as in the composition of the materials and systems (multi-component systems). It is possible to use environmental friendly water/alcoholic media as solvents. Since the complexes and formulations are prepared in protic solvents like water and/or alcoholic media, films can easily be prepared on polymeric or other (e.g. inorganic) substrates or combined with other polymer layers which are not stable in organic solvents usually used for polymer film manufacturing, but would allow to form another layer from water/alcoholic media. Ink-jet printing will be also readily available with water/alcoholic solvents. In case of a replication of SRGs and other topological surface structures using other polymer or non-polymer material, the initial photosensitive film with the photo-induced structure can be washed out by solvents. Anisotropic films and surface relief structures can be produced using the new material without expensive synthesis and purification of photochromic polymers wherein the photochromic unit must be covalently attached to the polymer backbone. And due to the ionic nature of the using materials, the film and products made from this film, e.g. SRGs, are thermally stable, at least until about 150 to 200° C.

Due to their superior chemical and physical (optical, mechanical) properties, the material of the present invention may be used in a wide variety of technical fields, and specifically in the field of technical and other optics, data storage and telecommunication. For example, the material may be used as a photosensitive medium, optical element, functional surface and/or template. Said elements may e.g. be diffractive elements, polarization elements, focusing elements or combinations of such elements. If the light-induced properties thereof are reversible, they can be used as or in elements for optical or optical/thermal switching. In such cases, the material is preferably prepared by a method as claimed in claim 27 or 28. Further, if the light-induced properties are reversible, it may be used as a medium for real-time holography or optical information processing. Alternatively, the photosensitive medium can be a medium for irreversible or reversible optical data storage. If the data storage is reversible, written information can subsequently be eliminated by irradiation or heating, if desired, whereafter another writing cycle is possible. In other applications, the material is used as a template, wherein the template surface is a surface for replication to another material or the command surface for aligning of liquid crystals, self-organization of particles. The surface may determine the chemical, mechanical and/or optical properties of the material, preferably selected from wetting/dewetting, hardness, reflectance and scattering.

FIG. 1 are AFM images of SRG written in material of the present invention (FIG. 1a, Example 1) and in poly((4-(4-trifluoromethylphenylazophenyl-4-oxy)butyl)methacrylate)-co-poly((2-(4-cyanobiphenyl-4-oxy)ethyl)methacrylate) (FIG. 1b, Example 2).

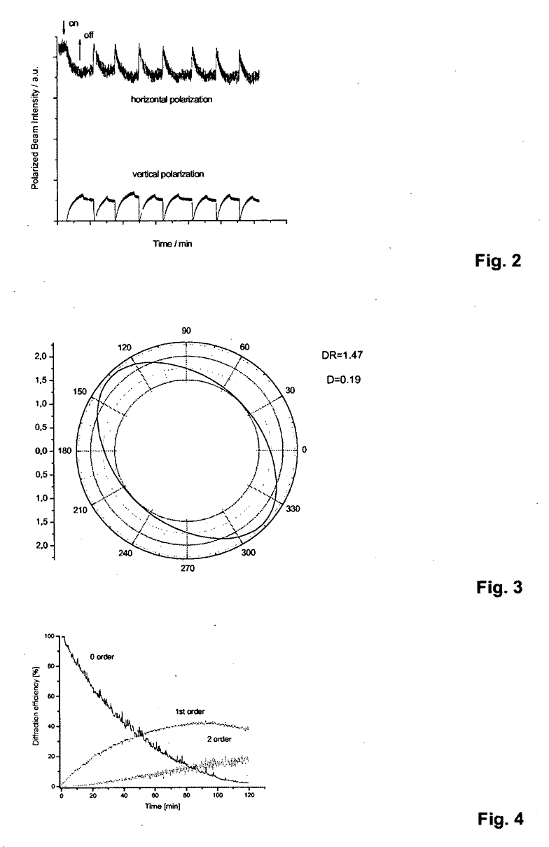

FIG. 2 illustrates the intensity of the orthogonally polarised components of the transmitted probe beam and switching between two-states under alternating irradiation (measurements on the material of Example 2 in FIG. 1b).

FIG. 3 is a polar diagram of absorption at 500 nm versus angle of polarization of the same material.

FIG. 4 illustrates kinetics of the diffracted probe beam during SRG writing into said material.

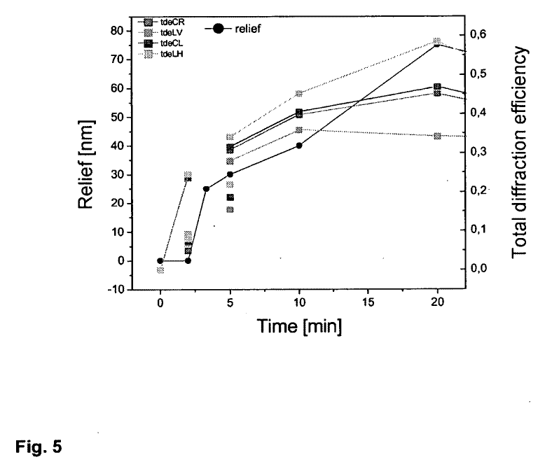

FIG. 5 illustrates total DE (different polarization of probe beam) and relief amplitude for orientation grating inscribed according to Example 3.

Below, the invention shall be exemplified further.

### EXAMPLE 1

### Recording

A film of about 2.5 μm thickness was prepared by casting the solution of 30 mg of poly{1-[4-(3-carboxy-4-hydroxyphenylazo)benzenesulfonamido]-1,2-ethanediyl, sodium salt} (PAZO) (Aldrich) in 1 ml of MeOH onto the glass substrate in a close chamber at room temperature. After drying at room temperature in air for 20 h the film was irradiated for 2 h with the interference pattern formed by two linearly orthogonally polarized beams with polarization planes at ±45° to the incidence plane. The irradiation wavelength was 488 nm, and the angle between beams was about of 12° resulting in a period of 2.3 μm. The intensities of interfering beams were equal to 250 mW/cm², the irradiation time was 40 min. The 1^{st} order diffraction efficiency of the SRG recorded was measured to be 35%, the kinetics of recording is illustrated in the FIG. 4. AFM image is shown in the FIG. 1a.

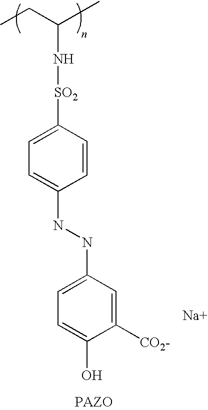

### EXAMPLE 2

### Photoinduced Anisotropy

A film of about 2.5 μm thickness was prepared by casting the solution of 30 mg of poly{1-[4-(3-carboxy-4-hydroxyphenylazo)benzenesulfonamido]-1,2-ethanediyl, sodium salt} (PAZO) (Aldrich) in 1 ml of MeOH onto the glass substrate in a close chamber at room temperature. After drying at room temperature in air for 20 h the film was irradiated by linearly polarised light of 488 nm and 250 mW/cm² for 1 h. Induced birefringence was stable, but could be erased by the light of proper polarization and induced again in any other direction (FIG. 2). The induced anisotropy was investigated by polarised UV-vis spectroscopy (FIG. 3, polar diagram). The value of optical dichroism has been found at 500 nm to be D=0, 19.

### EXAMPLE 3

### Orientation Grating Recording

A film of about 2.5 μm thickness was prepared by casting the solution of 30 mg of poly{1-[4-(3-carboxy-4-hydroxyphenylazo)benzenesulfonamido]-1,2-ethanediyl, sodium salt} (PAZO) (Aldrich) in 1 ml of MeOH onto a glass substrate in a close chamber at room temperature. After drying at room temperature in air for 20 h the film was irradiated for 20 min with the interference pattern formed by two circularly orthogonally polarized beams. The irradiation wavelength was 488 nm, and the angle between beams was about of 12° resulting in a period of 2.3 μm. The intensities of interfering beams were equal to 250 mW/cm². The total diffraction efficiency of the SRG recorded was measured to be up to 55% (confer to FIG. 5).

FIG. 5 displays the total DE (different polarization of probe beam) and relief amplitude for orientation grating inscribed in Example 3.

### EXAMPLE 4

### Stability of Orientation Grating

Orientation grating was written as described in example 3 for 5 min. After relaxation grating lost only 40% of DE. Annealing at 100° C. for 1 h did not lead to any loss of DE.

### EXAMPLE 5

### Surface Relief Grating Stability

SRG was written as described in example 1. Annealing of the film with the inscribed SRG at temperature of about 200° C. did not change the depth of the grating. No appreciable decrease in the DE was observed during heating at 200° C. for at least 6 h.

1. Homogeneous, photoactive film of a material consisting of or comprising a polyelectrolyte carrying residues which may undergo a photoreaction, selected from photoisomerizations, photocycloadditions and photoinduced rearrangements, the polyelectrolyte essentially consisting of or mainly comprising at least one structure according to formula I or formula II
[Pol(R*—P—R′)]ₒ^{on+}n/xA^{x-} (I),
or
n/xA^{x+}[Pol(R*—P—R′)]ₒ^{on-} (II),
and/or of formula III or IV:
[Pol(R¹*-Q-R^{1′})]ₒ^{on+}n/xA^{x-} (III),
or
n/xA^{x+}[Pol(R¹*-Q-R^{1′})]ₒ^{on-} (IV)
wherein Pol means a repeating unit of a linear or branched polymer chain, o indicates the number of the repeating unit of the polymer chain, and
(R*—P—R′) and (R¹*-Q-R^{1′}) are n-fold positively or negatively charged side chains of the repeating unit Pol wherein
P is a group which is capable of photo-induced E/Z isomerization,
R* is selected from optionally substituted and/or functionalized aryl-containing groups bound to the repeating unit Pol and to group P,
R′ is selected from optionally substituted and/or functionalized aryl-containing groups,
wherein at least one of R* and R′ is positively or negatively charged,
Q is a group capable of participating in a photocycloaddition, or capable of participating in a photoinduced rearrangement, or the so called Photo-Fries reaction,
R¹* is selected from optionally substituted or functionalized groups which have electron-accepting properties and is bound to the repeating unit Pol and to group Q,
R^{1′} is selected from optionally substituted or functionalized groups which have electron-accepting properties or comprise at least one aryl moiety or such (a) group(s) which together with Q form an aryl ring or heteroaryl ring,
wherein at least one of R¹* and R^{1′} is positively or negatively charged, or wherein the ring structure comprising R^{1′} and Q and/or a substituent thereon will carry at least one positive or negative charge,
A is a cation or anion which is oppositely charged,
n is 1, 2, 3, or 4,
x is 1 or 2, and
o is at least 2,
with the proviso that in one polyelectrolyte, groups Pol and/or [R—P—R′] and/or [R¹-Q-R^{1′}] all have the same sign.

2. Film according to claim 1, wherein the structures (I) to (IV) are of formulae
[Pol(R*—P—R′ⁿ⁺)]ₒn/xA^{x-} (I′),
or
n/xA^{x+}[Pol(R*—P—R′ⁿ⁻)]ₒ (II′),
or
[Pol(R¹*-Q-R^{1′n+})]ₒn/xA^{x-} (III′),
or
n/xA^{x-}[Pol(R¹*-Q-R^{1′n-})]ₒ (IV′)

3. Film according to claim 1 or 2, wherein group P and group Q in formulae (I) to (IV) are selected from —N═N—, —CR²═CR^{2′}— with R², R^{2′} being independently selected from H, CN or C₁-C₄ alkyl, and a group containing more than one —N═N— and/or —CR²═CR^{2′}— moieties in a electron-conjugated system.

4. Film according to any of claims 1 to 3, wherein in formulae (I) or (II), the aryl moieties of R, R are directly bound to the group P, and/or wherein in formulae (III) or (IV), R¹ and R^{1′} are selected from aryl moieties directly attached to Q, and —C(O)O— and —(CO)NR³ groups wherein R³ is H or a optionally substituted alkyl or aryl group.

5. Film according to any of claims 1 to 3, wherein the side chains of the polyelectrolyte are selected from monoazo groups, bisazo groups, trisazo groups, and preferably from azobenzene groups, bisazobenzene groups, trisazobenzene groups, and further from stilbene groups, cinnamate groups, imines, anthracene groups, coumarine groups, chalcone groups, p-phenylene diacrylates or diacrylamides, thymin derivatives, cytosine derivatives, merocyanines/spiropyranes and groups containing maleinic acid anhydride.

6. Film according to any of claims 1 to 5, wherein R* and R¹* are bound to the monomer units Pol via a carbon-carbon bond, or by way of an ether, ester, amine, amide, urea, guanidino, or sulfonamido group.

7. Film according to any of claims 1 to 6, comprising at least one additive which modifies the properties of the material, preferably selected from organic polymers, compounds which have film forming abilities, plasticizers, liquid crystals and photosensitive compounds differing from those as defined in claim 1.

8. Film according to claim 7, the film material additionally comprising a monomeric photosensitive molecule, which is capable to undergo polymerisation or to provide cross-linking, induced either by irradiation with light or by thermal treatment.

9. Film according to any of the preceding claims, wherein the film formation was carried out from an environmentally friendly solvent such as water-alcohol solution.

10. Film according to any of the preceding claims, wherein stacks of films were prepared from the said material and an additional polymer material soluble in organic solvent, but not soluble in water-alcohol solution to allow laminating the orientational and the surface relief structures by the additional polymer material to prevent the active layer and for preparing multifunctional stacks based on materials with different functions.

11. Film according to any of the preceding claims, either being placed as a layer on a substrate or in the form of a free-standing film, the film optionally being patterned.

12. Film according to any of the preceding claims, wherein at least one optical property of the film, preferably selected from refraction, absorption, birefringence, dichroism or gyrotropy, has been changed upon irradiation with light.

13. Film according to claim 12, wherein the changing optical properties are either
a. homogeneous through the material or
b. varied through the material or through restricted areas thereof.

14. Film according to claim 13, variant (b), wherein optical properties are modulated in one, two or three dimensions including modulation in the direction perpendicular to the film plane, in any direction in the film plane or along the axis tilted to the film plane.

15. Film according to any of the preceding claims wherein the film is placed on a substrate or is a free-standing film, at least one free surface of which exhibits a light-induced relief structure.

16. Film according to claim 15, wherein the relief structure is a regular pattern with height modulated in one or two dimensions.

17. Film according to claims 12 to 16, wherein the induced changes of optical properties or/and the induced relief structure are either
a. reversible or
b. irreversible.

18. Film according to claim 17, variant (a), wherein the changes of optical properties or/and of the relief structure are stable when kept at day light below the glass transition temperature or the decomposition temperature.

19. Film according to claims 17, variant (a), and 18, wherein the changes of optical properties or/and of the relief structure are cyclically induced with light and erased optically or thermally.

20. Method for the preparation of a film according to any of claims 1 to 11, comprising dissolving a polyelectrolyte essentially consisting of or mainly comprising at least one structure according to formula I, II, III or IV as defined in claim 1 and casting, spin coating, doctor's blading or ink-jet printing the solution onto a substrate, either in the form of a continuous film or having a predesigned pattern, wherein the material is applied as a chemically homogenous mixture throughout the film or patterned layer.

21. Method for the preparation of a material according to claim 13, variant (a), comprising preparing a film as defined in claim 20 and irradiating said film or a part of it with a homogeneous light field.

22. Method for the preparation of a material according to claims 13, variant (b), and 14, comprising preparing a film as defined in claim 20 and irradiating said film or part of it with an inhomogeneous light field, provided by a mask or by an interference pattern of at least two intersecting coherent beams.

23. Method according to claims 21 or 22, wherein either the wavelength, the irradiation time, the number of the irradiating beams and/or the polarization, the intensity, the incidence angle of at least one irradiating beam is varied to control the direction, the value and/or the modulation type of the induced optical anisotropy.

24. Method according to claims 22 or 23, further comprising varying the mask spacing or the period of the interference pattern in order to control the spatial modulation of optical anisotropy.

25. Method for the preparation of a material according to claims 15 and 16, comprising preparing a film as defined in claim 20 and inhomogeneously irradiating said film, preferably through a mask, with a focused beam, with near field, or with an interference pattern of at least two intersecting coherent beams.

26. Method for the preparation of a material according to claims 15 and 16, comprising preparing a film as defined in claim 25 and further changing of once inscribed structures (correcting or overwriting) by successive irradiation using the method according to claim 25.

27. Method according to claim 25 or 26, wherein structures with complicated (non-rectangular and non-sinusoidal) profile are prepared by multi-step (successive) irradiation, preferably with the interference patterns corresponding to the Fourier components of the desired profile.

28. Method according to claim 25 or 26, wherein complicated multidimensional structures are prepared by multi-step (successive) irradiation, preferably differing by the position of the material, irradiation conditions and/or the interference pattern.

29. Method for the preparation of a material according to claim 17, variant (a), or 18, comprising alternative preparation of a film as defined in claims 21 to 28 and erasure of the induced changes by either homogeneous irradiation of said film or part of it with a light or/and by heating it.

30. Method according to claim 29, wherein either the wavelength, the irradiation time, the polarization, the intensity, the incidence angle of erasing beam and/or the temperature, rate, time of heating is varied to control the velocity and degree of the erasure and the final state of the material.

31. Use of a film as claimed in any of claims 1 to 19 as a photosensitive medium, optical element, functional surface and/or template.

32. Use of a film as claimed in claims 17 to 19, wherein the light-induced property is reversible, as an element for optical or optical/thermal switching, the material preferably being prepared by a method according to claim 29 or 30.

33. Use of a film as claimed in claims 17, variant (a) and 19, wherein the light-induced property is reversible, as a medium for real-time holography or optical information processing.

34. Use according to claim 31, wherein the optical element is selected preferably from diffractive element, polarization element, focusing element or any combination of said elements.

35. Use according to claim 31, wherein the photosensitive medium is a medium for irreversible or reversible optical data storage.

36. Use according to claim 35, wherein written information can be eliminated by irradiation or heating, whereafter another writing cycle is possible.

37. Use according to claim 31, wherein the template surface is a surface for replication to another material or the command surface for aligning of liquid crystals, self-organization of particles.

38. Use according to claim 31, wherein the functional surface is the surface determining the chemical, mechanical, optical properties of the material, preferably selected from wetting/dewetting, hardness, reflectance, scattering.

39. Method for the preparation of a replica of a surface relief structure, comprising the following steps:
a. preparing a film according to any of claims 15 and 16 (“first material”) using a method as claimed in any of claims 25 to 28, to obtain a surface relief structure thereon;
b. covering said relief structure or a part thereof with a second material, selected from organic and inorganic-organic polymers and/or metals;
c. curing or hardening said second material, if required;
d. separating said second material from the surface relief grating of the first material, to obtain a (negative) replica and optionally
e. repeating steps (b) to (d), if more than one replica from the said surface relief structure shall be obtained.

40. Method for the preparation of a reproduction replica of an original surface relief structure, comprising the following steps:
a. preparing a material according to any of claims 15 and 16 (“first material”) using a method as claimed in any of claims 25 to 28, to obtain a surface relief structure thereon;
b. covering said relief structure or a part thereof with a second material, selected from organic and inorganic-organic polymers and/or metals;
c. curing or hardening said second material, if required;
d. separating said second material from the surface relief grating of the first material or washing out said first material with a suitable solvent to obtain a (negative) replica,
e. covering the negative relief structure of the replica with a third material, selected from organic and inorganic-organic polymers and metal,
f. curing or hardening said third metal, if required,
g. separating said third material from the surface relief grating of the second material, to obtain a (positive) replication replica of the original surface relief structure, and
h. repeating steps (e) to (g), if more than one reproduction replica from the said surface relief structure shall be obtained.
